(19) United States
(12) Patent Application Publication
(10) Pub. No.: US 2015/0096793 A1
(43) Pub. Date: Apr. 9, 2015

(54) METHOD FOR FORMING GRAPHENE CIRCUIT PATTERN AND PRODUCT WITH GRAPHENE CIRCUIT PATTERN

(71) Applicant: TAIWAN GREEN POINT ENTERPRISES CO., LTD., Taichung City (TW)

(72) Inventors: Pen-Yi LIAO, Taichung City (TW); Hui-Ching CHUANG, Taichung City (TW); Wen-Chia TSAI, Taichung City (TW)

(21) Appl. No.: 14/493,566

(22) Filed: Sep. 23, 2014

(30) Foreign Application Priority Data
Oct. 4, 2013 (TW) 102136026

(51) Int. Cl. H05K 3/10; H05K 1/09; H05K 3/28

(52) U.S. Cl. CPC H05K 3/102; H05K 3/28; H05K 1/097; H05K 2203/125
USPC 174/257; 264/259; 156/60; 156/247

(57) ABSTRACT

A method for forming a graphene circuit pattern on an object includes the following steps of: forming a patterned graphene layer on a surface of a film so as to form a laminate; and covering an object with the laminate so as to attach the patterned graphene layer to the object.

### CROSS-REFERENCE TO RELATED APPLICATION

This application claims priority of Taiwanese Patent Application No. 102136026, filed on Oct. 4, 2013.

### BACKGROUND OF THE INVENTION

1. Field of the Invention

The invention relates to a method for forming a circuit pattern on an object, more particularly to a method for forming a graphene circuit pattern on an object.

2. Description of the Related Art

U.S. Pat. No. 8,753,468 discloses a conventional method for transferring a graphene film to a planar surface of an object. This conventional method includes the following steps of: modifying a top surface of a graphene film by O₂ plasma, wherein the graphene film is grown on a metal foil; covering a thermo-releasable (or UV-releasable) material on the graphene film, followed by pressing and peeling off the thermo-releasable (or UV-releasable) material so as to attach the graphene film thereon (so called “the first transfer”); and covering the thermo-releasable material together with the graphene film on the planar surface of the object, followed by heating (or performing UV irradiation) so as to directly attach the graphene film onto the planar surface of the object (so called “the second transfer”).

U.S. Pat. No. 8,337,949 discloses another conventional method for forming a graphene pattern that includes depositing a graphitizing catalyst pattern on a glass substrate, and forming a graphene layer on the graphitizing catalyst pattern under high temperature using a carbonaceous material.

However, the conventional method in U.S. Pat. No. 8,753,468 not only requires two transfer steps but also damages the physical structure of the graphene layer while peeling off the thermo-releasable material therefrom. Moreover, such conventional method is merely suited for transferring the graphene film to the object having the planar surface, not to mention that the transferred graphene layer needs to be patterned afterwards, which increases the complexity of the manufacturing process. In addition, the conventional method in U.S. Pat. No. 8,337,949 requires expensive manufacturing equipment that increases manufacturing costs.

### SUMMARY OF THE INVENTION

Therefore, the object of the present invention is to provide a method that may alleviate the aforementioned drawbacks of the prior art, and to provide a product having a graphene circuit pattern.

According to one aspect of the present invention, a method for forming a graphene circuit pattern on an object includes the following steps of:

(a) forming a patterned graphene layer on a surface of a film so as to form a laminate; and

(b) covering the object with the laminate so as to attach the patterned graphene layer to the object.

Preferably, step (b) is conducted by injection molding a material of the object onto the film of the laminate, so as to form the object assembled with the film as one piece. The pattern graphene layer is indirectly attached to the object through the film.

Preferably, before step (b), the method of the present invention further includes a step of modifying a surface of the object to provide hydrophobic characteristics therefor, and step (b) is conducted by attaching the patterned graphene layer on the surface of the object that is modified. More preferably, step (b) further comprises removing the film from the patterned graphene layer.

Preferably, step (a) is conducted by preparing a graphene dispersion including graphenes, modifying the surface of the film to define a hydrophobic zone, and distributing the graphene dispersion to the film, so as to adhere the graphenes upon the hydrophobic zone to form the patterned graphene layer.

Preferably, step (a) is conducted by preparing a graphene dispersion including graphenes, forming a patterned adhesive layer on the surface of the film, and dipping the film into the graphene dispersion, so as to adhere the graphenes on the patterned adhesive layer to form the patterned graphene layer. More preferably, the step of forming the patterned adhesive layer comprises defining the adhesive layer into a patterned adhesive zone and a non-adhesive zone, so as to adhere the graphenes on the patterned adhesive zone.

Preferably, in step (b), attaching the patterned graphene layer of the laminate on the surface of the object is conducted by using a thermal pressing apparatus that has a pressing surface corresponding in shape to the surface of the object.

Preferably, the method further includes, before step (a), the following steps of:

providing a first electrode and a second electrode in an electrolyte solution, the first electrode being composed of a graphite material;

applying voltage to the first and second electrodes to perform electrolysis reaction, such that the graphite material exfoliates to form a plurality of the graphenes dispersed in the electrolyte solution; and

separating the graphenes from the electrolyte solution. More preferably, prior to step (a), the method further comprises the step of dispersing the graphenes separated from the electrolyte solution in a liquid to form a graphene dispersion.

Another method of the present invention for forming a graphene circuit pattern on an object includes the following steps of:

(a) forming a graphene layer on a surface of a film so as to form a laminate; and

(b) covering the object with the laminate to directly attach the graphene layer to the object, followed by patterning the graphene layer to form a patterned graphene layer and removing the film so as to retain the patterned graphene layer on a surface of the object.

Preferably, step (a) is conducted by preparing a graphene dispersion including graphenes, forming an adhesive layer on the surface of the film, and dipping the film into the graphene dispersion so as to adhere the graphenes to the surface of the film to form the graphene layer.

Preferably, in step (b), attaching the graphene layer to the object is conducted using a thermal pressing apparatus that has a pressing surface corresponding in shape to the surface of the object.

Preferably, the method further includes, before step (a), the following steps of:

providing a first electrode and a second electrode in an electrolyte solution, the first electrode being composed of a graphite material;

applying voltage to the first and second electrodes to perform electrolysis reaction, such that the graphite material exfoliates to form a plurality of the graphenes in the electrolyte solution; and

separating the graphenes from the electrolyte solution.

According to another aspect of the present invention, a product with a graphene circuit pattern comprises an object, a film on a surface of the object, and a patterned graphene layer on a surface of the film, wherein the patterned graphene layer is indirectly attached to the object through the film.

Preferably, the surface of the object is non-planar.

Preferably, the product is a casing of an electronic product.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic diagram of a first preferred embodiment of a method for forming a graphene circuit pattern on an object according to the invention, illustrating a step of forming graphenes;

FIG. 2 is a schematic view of the first preferred embodiment, illustrating a step of forming a graphene dispersion;

FIG. 3 is a schematic view of the first preferred embodiment, illustrating a step of forming a patterned graphene layer on a film;

FIG. 4 is a schematic view of the first preferred embodiment, illustrating a step of attaching the patterned graphene layer onto an object;

FIG. 5 is a sectional view taken along line V-V of FIG. 4, illustrating that the step of attaching the patterned graphene layer on the object is conducted by indirectly attaching the patterned graphene layer onto the object through the film;

FIG. 6 is a schematic view of a second preferred embodiment of a method for forming a graphene circuit pattern on an object according to the invention, illustrating a step of forming an adhesive layer on the film;

FIG. 7 is a schematic view of the second preferred embodiment, illustrating that the adhesive layer is defined into a patterned adhesive zone and a non-adhesive zone;

FIG. 8 is a schematic view of the second preferred embodiment, illustrating a step of adhering graphenes onto the patterned adhesive zone to form the patterned graphene layer;

FIG. 9 is a schematic view of the second preferred embodiment, illustrating a step of covering a laminate containing the film and the patterned graphene layer on a surface of the object using a thermal pressing apparatus;

FIG. 10 is a schematic view of a third preferred embodiment of a method for forming a graphene circuit pattern on an object according to the invention, illustrating a step of forming a laminate including the film and a graphene layer;

FIG. 11 is a schematic view of the third preferred embodiment, illustrating a step of covering the laminate onto the object using the thermal pressing apparatus;

FIG. 12 is a schematic view of the third preferred embodiment, illustrating a step of patterning the graphene layer to form the patterned graphene layer; and

FIG. 13 is a sectional view of a product that is made by the third preferred embodiment.

### DETAILED DESCRIPTION OF THE PREFERRED EMBODIMENTS

Before the present invention is described in greater detail, it should be noted that like elements are denoted by the same reference numerals throughout the disclosure.

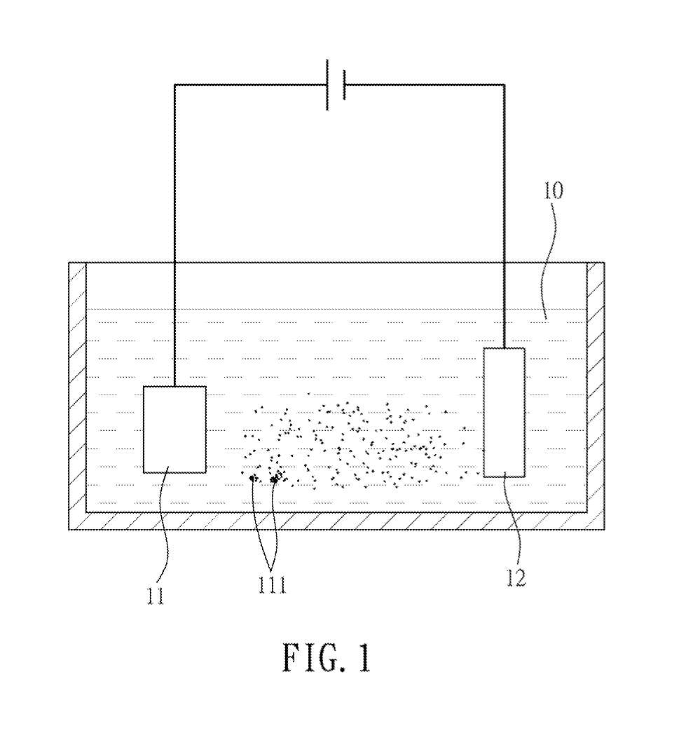

Referring to FIGS. 1 to 5, the first preferred embodiment of a method for forming a graphene circuit pattern on an object according to the present invention includes the following steps of:

(a) forming a patterned graphene layer 22 on a surface of a film 2, so as to form a laminate; and

(b) covering the object 3 with the laminate so as to attach the patterned graphene layer 22 onto the object 3.

Prior to step (a), in this embodiment, the method of the present invention further includes a graphene forming step. As shown in FIG. 1, the graphene forming step is conducted as follows:

A first electrode 11 and a second electrode 12 are provided in an electrolyte solution 10. The first electrode 11 is composed of a graphite material, and the second electrode 12 can be composed of the graphite material or of a metallic material. The graphite material may be, but is not limited to, graphite, highly-oriented pyrolytic graphite (HOPG), PAN-based graphite (pitch-based graphite) or coal. The metallic material may be a noble metal, such as Pt, Ag, Au, Ir, Os, Pd, Rh, Ru, and the like. In this embodiment, the metallic material is exemplified as Pt for the second electrode 12. The electrolyte solution 10 primarily contains electrolytes, such as HBr, HCl, and/or H₂SO₄. In this embodiment, the electrolyte solution 10 may also contain an oxidizing agent, such as K₂Cr₂O₇, HMnO₂, and/or KMnO₄. It is worth noting that pH value of the electrolyte solution 10 in this embodiment ranges from 1 to 10. Thereafter, the first and second electrodes 11, 12 are applied with a voltage to perform electrolysis reaction, such that the graphite material of the first electrode 11 (or the second electrode 12) exfoliates to form a plurality of graphenes 111 dispersed in the electrolyte solution 10. The graphenes 111 are then separated from the electrolyte solution 10. In this embodiment, the separation of the graphenes 111 is conducted by ultra-high speed centrifugation. It is worth noting that additives, such as KOH, may be added into the electrolyte solution 10 prior to the electrolysis reaction, in order to obtain the graphenes 111 with better qualities.

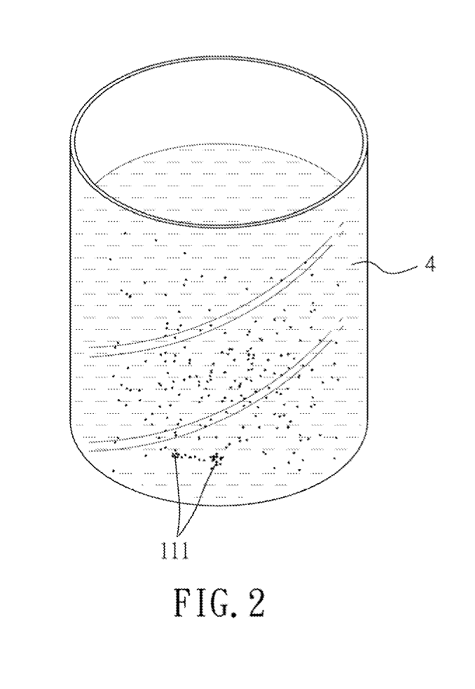

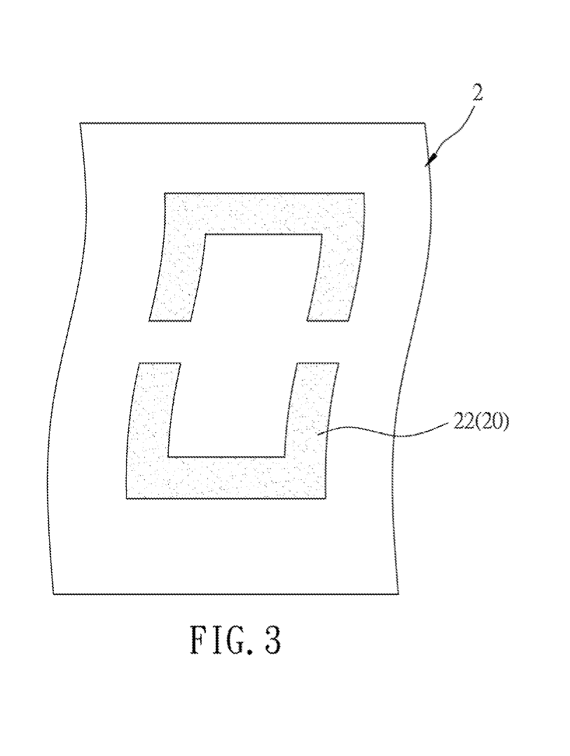

As shown in FIG. 2, in step (a), the graphenes 111 obtained from the graphene forming step are dispersed in a liquid 4 to form a graphene dispersion. The liquid 4 may be, but is not limited to, isopropyl alcohol (IPA), N-methyl pyrrolidinone (NPM), dimethylformamide (DMF), or tetrahydrofuran (THF). As shown in FIG. 3, the surface of the film 2 is modified to define a hydrophobic zone 20, and then the graphene dispersion is distributed onto the film 2, so as to adhere the graphenes 111 upon the hydrophobic zone 20 to form the patterned graphene layer 22.

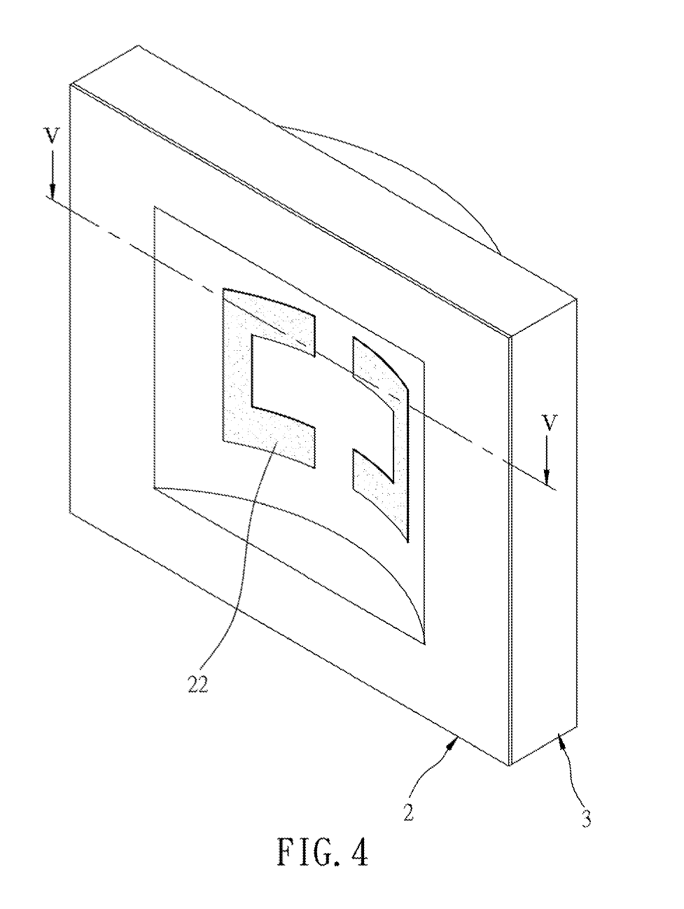

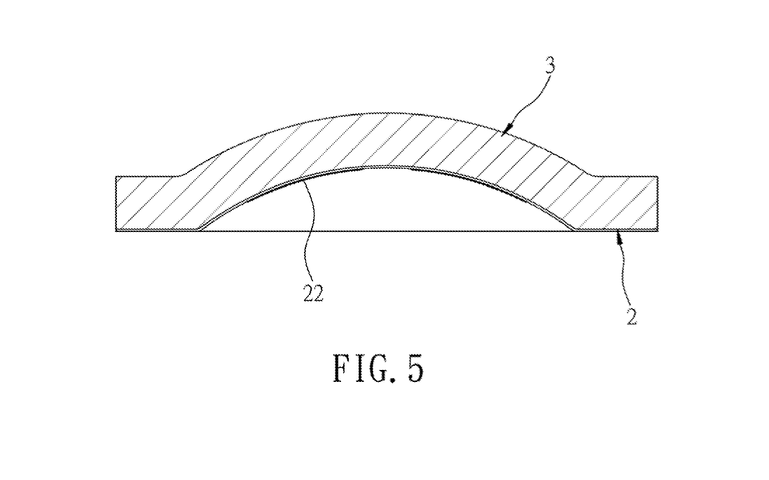

In this embodiment, as shown in FIGS. 4 and 5, step (b) is conducted by injection molding a material of the object 3 onto the film 2 of the laminate, so as to form the object 3 that is assembled with the film 2 as one piece. A product is thereby obtained, which contains the object 3, the patterned graphene layer 22, and the film 2, wherein the patterned graphene layer 22 is indirectly attached to the object 3 through the film 2. The product can be a casing of an electronic product, such as a cellular phone, GPS and so forth. It should be noted that, the surface of the object 3, where the film 2 binds, is not limited to be planar. That is to say, a protruding, indenting, or curved surface of the object 3 will still suffice according to the present invention.

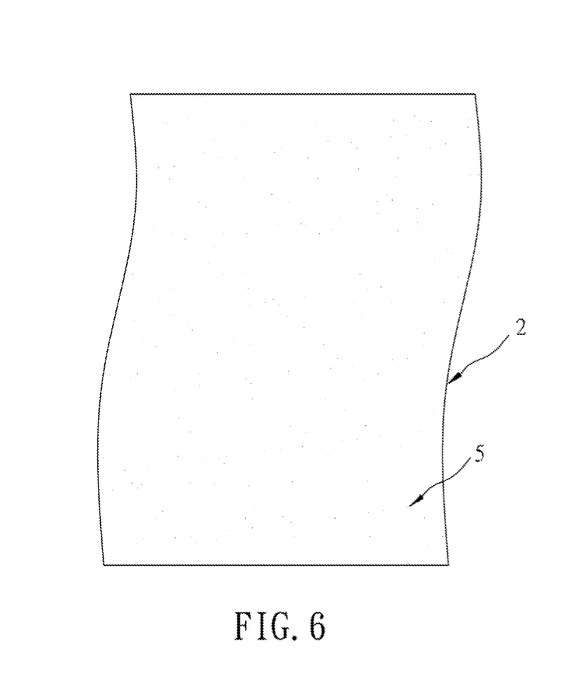

Referring to FIGS. 6 to 9, the second preferred embodiment of the method of this invention is similar to that of the first preferred embodiment. The differences therebetween are as follows.

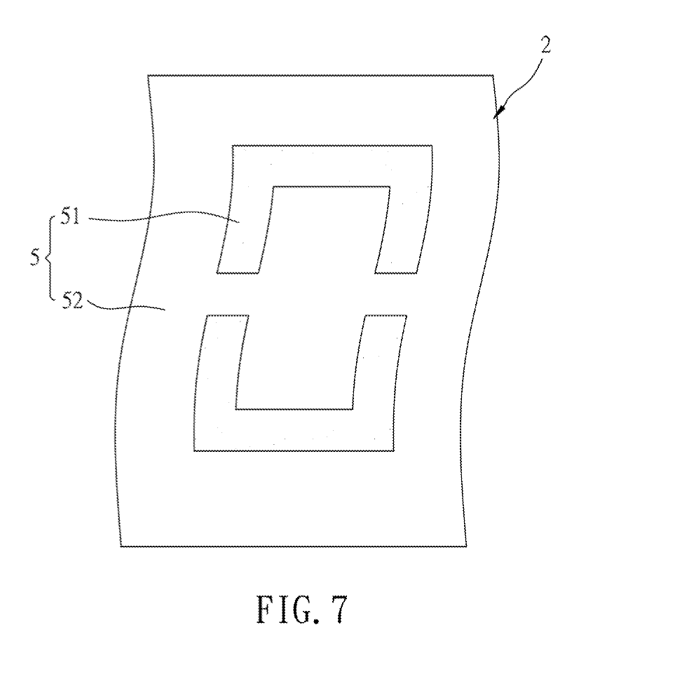

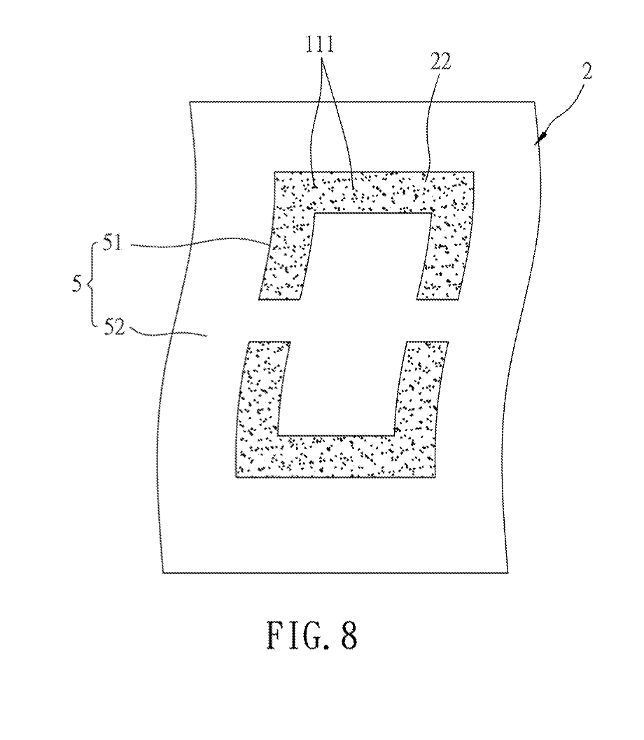

As shown in FIGS. 6 and 8, step (a) of this embodiment is conducted by preparing the graphene dispersion including the graphenes 111, forming an adhesive layer 5 on the surface of the film 2 (see FIG. 6), defining the adhesive layer 5 into a patterned adhesive zone 51 and a non-adhesive zone 52 (see FIG. 7), and dipping the film 2 into the graphene dispersion so as to adhere the graphenes 111 onto the patterned adhesive zone 51 to form the patterned graphene layer 22.

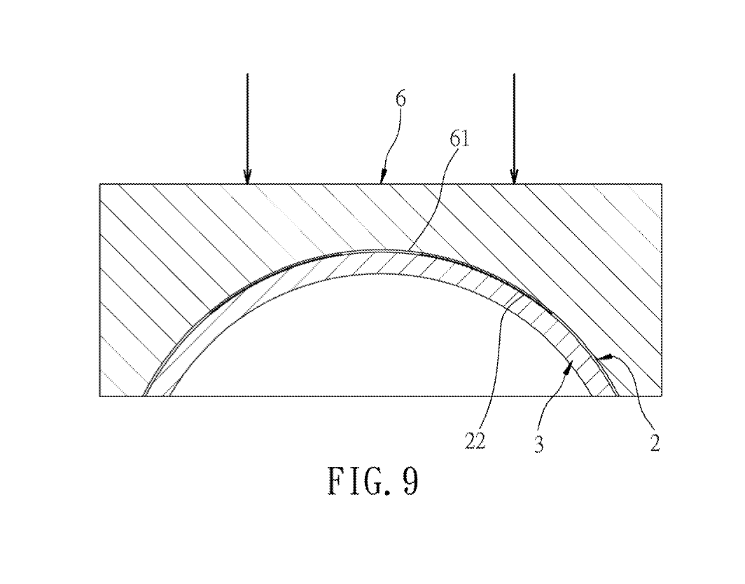

Prior to step (b), this embodiment further includes a step of modifying a surface of the object 3 to provide hydrophobic characteristics therefor. Such step can be performed using plasma or a solvent (such as silane). As shown in FIG. 9, step (b) of this embodiment is conducted by attaching the patterned graphene layer 22 of the laminate on the modified surface of the object 3, followed by removing the film 2 therefrom to retain the patterned graphene layer 22 on the object 3. To be specific, attaching the patterned graphene layer 22 of the laminate to the object 3 is conducted using a thermal pressing apparatus 6 that has a pressing surface 61 corresponding in shape to the surface of the object 3.

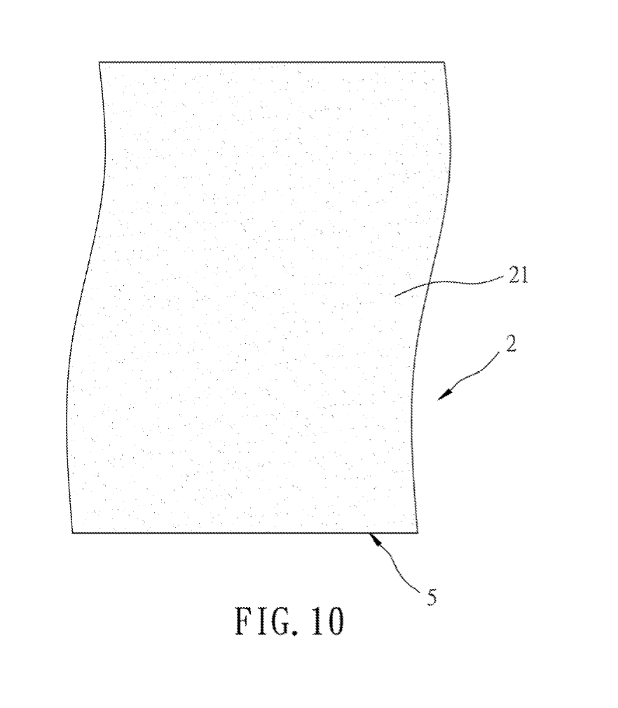

Referring to FIGS. 10 to 12 and further referring back to FIGS. 2 and 6, the third preferred embodiment of the method according to the present invention is similar to that of the first preferred embodiment, except that the graphene layer 21 formed in step (a) is not patterned and a patterning procedure is performed after the graphene layer 21 is attached to the object 3. To be specific, the method of the third preferred embodiment includes the aforementioned graphene-forming step, a graphene layer-forming step, and a transferring step.

In this embodiment, the graphene layer-forming step is conducted by preparing a graphene dispersion including the graphenes 111, which are obtained from the graphene-forming step (see FIG. 2), forming an adhesive layer 5 on the surface of the film 2 (see FIG. 6), and dipping the film 2 into the graphene dispersion to adhere the graphenes 111 to the surface of the film 2 so as to form a laminate composed of the film 2 and a graphene layer 21 (see FIG. 10).

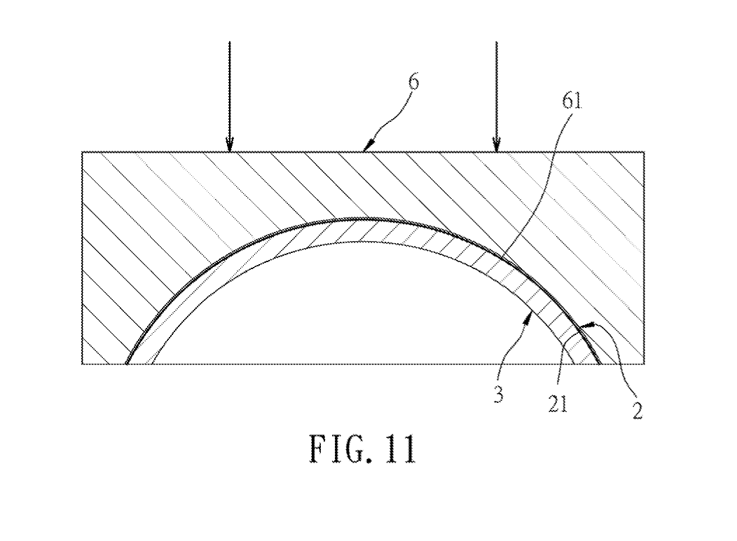

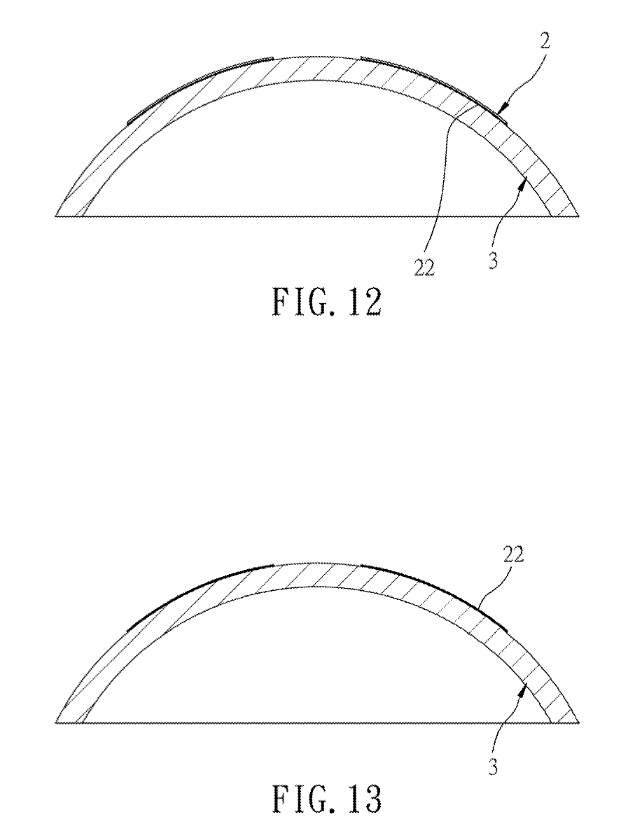

In the transferring step, as shown in FIGS. 11 to 13, the object 3 is covered with the laminate such that the graphene layer 21 is directly attached to the object 3, followed by patterning the graphene layer 21 to form a patterned graphene layer 22, and removing the film 2 so as to retain the patterned graphene layer 22 on a surface of the object 3. In this embodiment, attaching the graphene layer 21 to the object 3 is conducted using a thermal pressing apparatus 6 that has a pressing surface 61 corresponding in shape to the surface of the object 3. Patterning the graphene layer 21 is conducted using a laser beam to cut off unwanted portions of the graphene layer 21 to obtain the patterned graphene layer 22 as shown in FIG. 12. Lastly, as shown in FIG. 13, the film 2 is removed so as to retain the patterned graphene layer 22 on the surface of the object 3. It is worth noting that, the surface of the object 3 is not limited to be planar according to the present invention.

As shown in FIG. 13, a product made respectively by the methods of the present invention is shown to include the object 3 and the patterned graphene layer 22. It is worth noting that the patterned graphene layer 22 of the product made by the method of the first preferred embodiment is indirectly attached to the object 3 through the film 2 (see FIG. 4). On the other hand, the patterned graphene layer 22 of the product made by the method of the third preferred embodiment is directly attached to the surface of the object 3.

To sum up, the method of the present invention is capable of transferring the patterned graphene layer 22 simply via one single step, thereby lowering the risk of the patterned graphene layer 22 being damaged during the transferring step. Moreover, the method of the present invention applies to the object 3 that has a non-planar surface, so as to result in a wide range of applications.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A method for forming a graphene circuit pattern on an object, comprising the following steps of:
(a) forming a patterned graphene layer on a surface of a film so as to form a laminate; and
(b) covering an object with the laminate so as to attach the patterned graphene layer to the object.

2. The method according to claim 1, wherein step (b) is conducted by injection molding a material of the object onto the film of the laminate, so as to form the object assembled with the film as one piece, the patterned graphene layer being indirectly attached to the object through the film.

3. The method according to claim 1, further comprising, before step (b), modifying a surface of the object to provide hydrophobic characteristics for the surface of the object, step (b) being conducted by attaching the patterned graphene layer of the laminate on the surface of the object that is modified.

4. The method according to claim 3, wherein step (b further comprising removing the film from the patterned graphene layer.

5. The method according to claim 1, wherein step (a) is conducted by preparing a graphene dispersion including graphenes, modifying the surface of the film to define a hydrophobic zone, and distributing the graphene dispersion to the film, so as to adhere the graphenes upon the hydrophobic zone to form the patterned graphene layer.

6. The method according to claim 2, wherein step (a) is conducted by preparing a graphene dispersion including graphenes, modifying the surface of the film to define a hydrophobic zone, and distributing the graphene dispersion to the film, so as to adhere the graphenes upon the hydrophobic zone to form the patterned graphene layer.

7. The method according to claim 1, wherein step (a) is conducted by preparing a graphene dispersion including graphenes, forming a patterned adhesive layer on the surface of the film, and dipping the film into the graphene dispersion, so as to adhere the graphenes on the patterned adhesive layer to form the patterned graphene layer.

8. The method according to claim 3, wherein step (a) is conducted by preparing a graphene dispersion including graphenes, forming a patterned adhesive layer on the surface of the film, and dipping the film into the graphene dispersion, so as to adhere the graphenes on the patterned adhesive layer to form the patterned graphene layer.

9. The method according to claim 7, wherein the step of forming the patterned adhesive layer comprises defining the adhesive layer into a patterned adhesive zone and a non-adhesive zone, so as to adhere the graphenes on the patterned adhesive zone.

10. The method according to claim 1, wherein, in step (b), attaching the patterned graphene layer of the laminate on the surface of the object is conducted using a thermal pressing apparatus that has a pressing surface corresponding in shape to the surface of the object.

11. The method according to claim 1, prior to step (a), further comprising the steps of:
providing a first electrode and a second electrode in an electrolyte solution, the first electrode being composed of a graphite material;
applying voltage to the first and second electrodes to perform electrolysis reaction, such that the graphite material exfoliates to form a plurality of graphenes dispersed in the electrolyte solution; and
separating the graphenes from the electrolyte solution.

12. The method according to claim 11, prior to step (a), further comprising the step of dispersing the graphenes separated from the electrolyte solution in a liquid to form a graphene dispersion.

13. A method for forming a graphene circuit pattern on an object, comprising the following steps of:
(a) forming a graphene layer on a surface of a film so as to form a laminate; and
(b) covering the object with the laminate such that the graphene layer is directly attached to the object, followed by patterning the graphene layer to form a patterned graphene layer, and removing the film so as to retain the patterned graphene layer on a surface of the object.

14. The method according to claim 13, wherein step (a) is conducted by preparing a graphene dispersion including graphenes, forming an adhesive layer on the surface of the film, and dipping the film into the graphene dispersion, so as to adhere the graphenes to the surface of film to form the graphene layer.

15. The method according to claim 13, wherein, in step (b), attaching the graphene layer to the object is conducted using a thermal pressing apparatus that has a pressing surface corresponding in shape to the surface of the object.

16. The method according to claim 13, wherein, in step (b), attaching the graphene layer to the object is conducted using a thermal pressing apparatus that has a pressing surface corresponding in shape to the surface of the object.

17. The method according to claim 13, before step (a), further comprising the following steps of:
providing a first electrode and a second electrode in an electrolyte solution, the first electrode being composed of a graphite material;
applying voltage to the first and second electrodes to perform electrolysis reaction, such that the graphite material exfoliates to form a plurality of graphenes dispersed in the electrolyte solution; and
separating the graphenes from the electrolyte solution.

18. A product with a graphene circuit pattern, comprising:
an object;
a film on a surface of the object; and
a patterned graphene layer on a surface of the film, wherein the patterned graphene layer is indirectly attached to the object through the film.

19. The product according to claim 18, wherein, the surface of the object is non-planar.

20. The product according to claim 18, wherein the product is a casing of an electronic product.
